(19) United States
(12) Patent Application Publication
(10) Pub. No.: US 2017/0179320 A1
(43) Pub. Date: Jun. 22, 2017

(54) SYSTEM AND METHOD FOR FABRICATING SOLAR PANELS USING BUSBARLESS PHOTOVOLTAIC STRUCTURES

(71) Applicant: SolarCity Corporation, San Mateo, CA (US)

(72) Inventor: Christoph G. Erben, Los Gatos, CA (US)

(73) Assignee: SolarCity Corporation, San Mateo, CA (US)

(21) Appl. No.: 14/973,503

(22) Filed: Dec. 17, 2015

(51) Int. Cl. H01L 31/0465; H01L 21/683; H01L 21/67; H01L 31/0747; H01L 31/20

(52) U.S. Cl. CPC H01L 31/0465; H01L 31/0747; H01L 31/202; H01L 31/206; H01L 21/67098; H01L 21/6838

(57) ABSTRACT

A photovoltaic structure can include two or more sets of parallel conductive fingers on a top surface and a bottom surface, such that the fingers can collect an electric current from the underlying photovoltaic structure. A scribing system can scribe a groove of a predetermined depth near and perpendicular to the plurality of fingers of the photovoltaic structure, and the photovoltaic structure can be cleaved along the groove to produce multiple strips that each can include a set of parallel fingers. An adhesive dispense system may deposit a band of conductive adhesive that can overlap a set of parallel fingers on each strip, and the strips may be overlapped over the conductive adhesive to form a string of cascaded strips. An adhesive-curing system can include an oven that may cure the conductive adhesive on one or more strips of the string at a time.

### FIELD OF THE INVENTION

This relates to solar panel fabrication, including depositing a conductive adhesive along a solar cell strip's set of fingers to collect current from the fingers, and to bond the strip to a neighboring strip in a string.

### DEFINITIONS

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A solar cell may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a poly-crystalline silicon-based solar cell, or a strip thereof.

### BACKGROUND

Advances in photovoltaic technology, which are used to make solar panels, have helped solar energy gain mass appeal among those wishing to reduce their carbon footprint and decrease their monthly energy costs. However, the panels are typically fabricated manually, which is a time-consuming and error-prone process that makes it costly to mass-produce reliable solar panels.

Solar panels typically include one or more strings of complete solar cells. Adjacent solar cells in a string may overlap one another in a cascading arrangement. For example, continuous strings of solar cells that form a solar panel are described in U.S. patent application Ser. No. 14/510,008, filed Oct. 8, 2014 and entitled “Module Fabrication of Solar Cells with Low Resistivity Electrodes,” the disclosure of which is incorporated herein by reference in its entirety. Producing solar panels with a cascaded cell arrangement can reduce the resistance due to inter-connections between the strips, and can increase the number of solar cells that can fit into a solar panel.

One method of making such a panel includes sequentially connecting the busbars of adjacent cells and combining them. One type of panel (as described in the above-noted patent application) includes a series of cascaded strips created by dividing complete solar cells into strips, and then cascading the strips to form one or more strings.

Precise and consistent division of solar cells into strips and alignment of strips or cells when forming a cascade arrangement is critical to ensure proper electrical and physical connections, but such alignment can be difficult to reliably achieve in high volumes if performed manually.

To make matters worse, typical photovoltaic structures can include a plurality of copper fingers, coupled by copper busbars that collect electrical current from the fingers. Unfortunately, the copper busbars can take up a significant surface area of a photovoltaic structure, and can impose stresses onto the photovoltaic structure.

A problem of using copper on a photovoltaic structure is that copper tends to add stresses onto the photovoltaic structure during the lifetime of a solar panel. For example, as the outdoor temperature cycles throughout the day, daytime heat can cause the copper to undergo thermal expansion. Also as temperatures cool during the evening and night, the copper can undergo thermal contraction. These stresses on the copper busbars can either cause the copper busbars to crack, and/or can cause stress on the underlying photovoltaic structure. Since copper makes up a significant portion of the photovoltaic structure, the stress caused by the copper makes up a significant source of the stresses on the photovoltaic structures during the lifetime of the solar panel.

### SUMMARY

One embodiment provides a busbarless photovoltaic structure. The photovoltaic structure can include a first set of finger electrodes that may be positioned along a first side of the photovoltaic structure, so that a respective finger electrode on the first side can harvest current from the first side of the photovoltaic structure. The photovoltaic structure can also include a segment of conductive adhesive on the first side covering one edge of the finger electrodes, such that the conductive adhesive may transfer a current harvested by the finger electrodes to a conductor.

In some embodiments, a respective finger electrode can include an electroplated copper layer.

In some embodiments, the segment of conductive adhesive can have an elongated shape and may be perpendicular to the finger electrodes.

In some embodiments, the finger electrodes may be substantially parallel to each other.

In some embodiments, the photovoltaic structure can be a double-sided tunneling heterojunction photovoltaic structure. The photovoltaic structure can include a base layer along with first and second intrinsic tunneling layers deposited on both surfaces of the base layer. The photovoltaic structure can also include an amorphous silicon emitter layer, and an amorphous silicon surface field layer. The photovoltaic structure can absorb light from the first side and a second side of the photovoltaic structure.

The photovoltaic structure can include a plurality of finger electrodes positioned along the second side of the photovoltaic structure, so that a respective finger electrode on the second side may harvest a current from the second side of the photovoltaic structure.

In some embodiments, the photovoltaic structure can be obtained by dividing a substantially square shaped photovoltaic structure.

One embodiment provides a solar panel, which can include a plurality of photovoltaic strips arranged into a plurality of subsets. Each subset can include a number of photovoltaic strips electrically coupled in series. Also, a respective photovoltaic strip of the subset can include a plurality of finger electrodes on a first side of the respective photovoltaic strip. A segment of conductive adhesive on the first side can cover one edge of the finger electrodes to collect a current harvested by the finger electrodes. The subsets of photovoltaic strips can be electrically coupled in parallel.

In some embodiments, a respective photovoltaic strip in a subset can be obtained by dividing a substantially square shaped photovoltaic structure.

In some embodiments, the photovoltaic structure may be a double-sided tunneling heterojunction photovoltaic structure that can absorb light from the first side and a second side of the photovoltaic structure.

In some embodiments, a plurality of finger electrodes may be positioned along the second side of the photovoltaic strip. A respective finger electrode on the second side may harvest a current from the second side of the photovoltaic strip.

In some embodiments, a respective finger electrode can include an electroplated copper layer.

In some embodiments, the conductive adhesive on the first side of the respective photovoltaic strip may be in contact with an edge of the second side of a neighboring photovoltaic strip in the subset.

In some embodiments, the conductive adhesive may be electrically coupled to finger electrodes on the second side of the neighboring photovoltaic strip.

One embodiment provides a system that can fabricate a solar panel. During operation, the system can electrically couple a plurality of photovoltaic strips in series to form a string. A respective photovoltaic strip can include a plurality of finger electrodes on both sides of the respective photovoltaic strip, and a segment of conductive adhesive on a first side of the photovoltaic strip. The conductive adhesive may cover one edge of finger electrodes on the first side. The system may electrically couple multiple strings in parallel, and may proceed to apply a front-side cover and a back-side cover over the strings.

The system may obtain the photovoltaic strips by first obtaining a plurality of substantially square shaped photovoltaic structures, and then dividing each substantially square shaped photovoltaic structure into multiple photovoltaic strips.

In some embodiments, the system may electrically couple the plurality of photovoltaic strips in series. In doing so, the system may overlap a bottom edge of a first photovoltaic strip on top of a conductive adhesive on a top edge of a second photovoltaic strip. The conductive adhesive may electrically couple finger electrodes on the bottom side of the first photovoltaic strip to finger electrodes on the top side of the second photovoltaic strip.

In some embodiments, the system may cure conductive adhesive on the string to physically couple the strips in the string.

In some embodiments, the system may cure the conductive adhesive by exposing the conductive adhesive to air heated to 150 degrees Celsius for 3 minutes.

In some embodiments, conductive adhesive on the respective photovoltaic strip may transfer current harvested from the finger electrodes to a conductive contact. Then, the system may electrically couple multiple strings in parallel by coupling a pair of contacts of a first string to a pair of contacts of a second string.

### BRIEF DESCRIPTION OF THE FIGURES

FIG. 1A presents a diagram illustrating an exemplary double-sided tunneling heterojunction solar cell, in accordance with an embodiment of the present invention.

FIG. 1B shows one example of a photovoltaic structure before being divided into multiple strips, according to one embodiment of the invention.

FIG. 1C shows an exemplary conductive grid and blank space pattern on a front surface of a photovoltaic structure, according to one embodiment of the invention.

FIG. 1D shows an exemplary conductive grid and blank space pattern on the back surface of the photovoltaic structure, according to one embodiment of the invention.

FIG. 2A shows multiple strips, which are the result of separating a photovoltaic structure along a set of grooves, according to one embodiment of the invention.

FIG. 2B shows a cross-sectional view of a photovoltaic structure prior to being cleaved, according to one embodiment of the invention.

FIG. 2C shows a cascaded arrangement of three strips after a photovoltaic structure is cleaved, according to one embodiment of the invention.

FIG. 3 shows a sequence of steps for processing photovoltaic structures to produce a string, according to one embodiment of the invention.

FIG. 4 shows a scribing system for simultaneously scribing multiple photovoltaic structures, according to an embodiment of the invention.

FIG. 5 shows an adhesive dispenser, according to an embodiment of the invention.

FIG. 6 shows an adhesive curing system, according to an embodiment of the invention.

FIG. 7 shows an exemplary system-controlling apparatus, according to an embodiment of the invention.

FIGS. 8A and 8B show an exemplary method for processing a plurality of photovoltaic structures in parallel to form a string, according to an embodiment of the invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

A string-forming system is provided that can process multiple photovoltaic structures in parallel to form a string, without significantly damaging the photovoltaic structures. Each photovoltaic structure can include a plurality of elongated conductive electrodes (hereinafter referred to as “fingers”) arranged into multiple separate regions of the photovoltaic structure (hereinafter referred to as “strips”). Each set of fingers can collect current from its strip. Unlike conventional photovoltaic structures, the strips of the present invention may not include a metallic busbar that would otherwise be used to collect current from the set of fingers. Without metallic busbars, such as a copper busbar, the strips can become more robust as they may not be susceptible to the problems that metallic busbars may cause to a solar panel during the manufacture or lifetime of the solar panel.

For example, copper busbars can add stresses onto a photovoltaic structure as the copper undergoes thermal expansion and contraction during the lifetime of a solar panel. These stresses can cause the copper busbars to crack, and/or can damage the strip's underlying photovoltaic structure, which can degrade the current that can be produced by the strip.

Another problem of using copper is that the copper can become detached from the strip's underlying layers, which can reduce the current that flows out of the photovoltaic structure, and can reduce the amount of power produced by the solar panel. To make matters worse, the copper is sensitive to corrosion, which can further decrease the current that can be transmitted across the copper busbar.

In some embodiments, the amount of metallic material used in solar panels can be reduced by replacing metallic features of a photovoltaic structure with a more flexible and resilient material, such as a conductive adhesive in the form of a paste and/or film. The design of the string-forming system can be adapted to apply and cure conductive adhesive on a plurality of photovoltaic structures at a time, which can reduce the average amount of time needed to process each individual photovoltaic structure. Moreover, the redesigned string-forming system can even result in a decreased cost for fabricating solar panels by eliminating the cost and complexity associated with forming and interconnecting the copper busbars in a string. The string-forming system can operate within an automated assembly line that can manufacture complete solar panels that may include multiple strings of cascaded strips.

### Busbarless Photovoltaic Structure

The photovoltaic structure can include a set of fingers that are not coupled together via a metallic busbar (e.g., a copper busbar). This allows two strips to be electrically coupled to each other without creating a connection from one strip to its copper busbar, to a copper busbar on a second strip via a conductive adhesive, and then to the other strip. In some embodiments, instead of using metallic busbars, the present invention can use a conductive adhesive. For example, the plurality of finger electrodes on a strip can become electrically coupled together via the same conductive adhesive that can be used to bond the strip's top surface to a bottom surface of another strip.

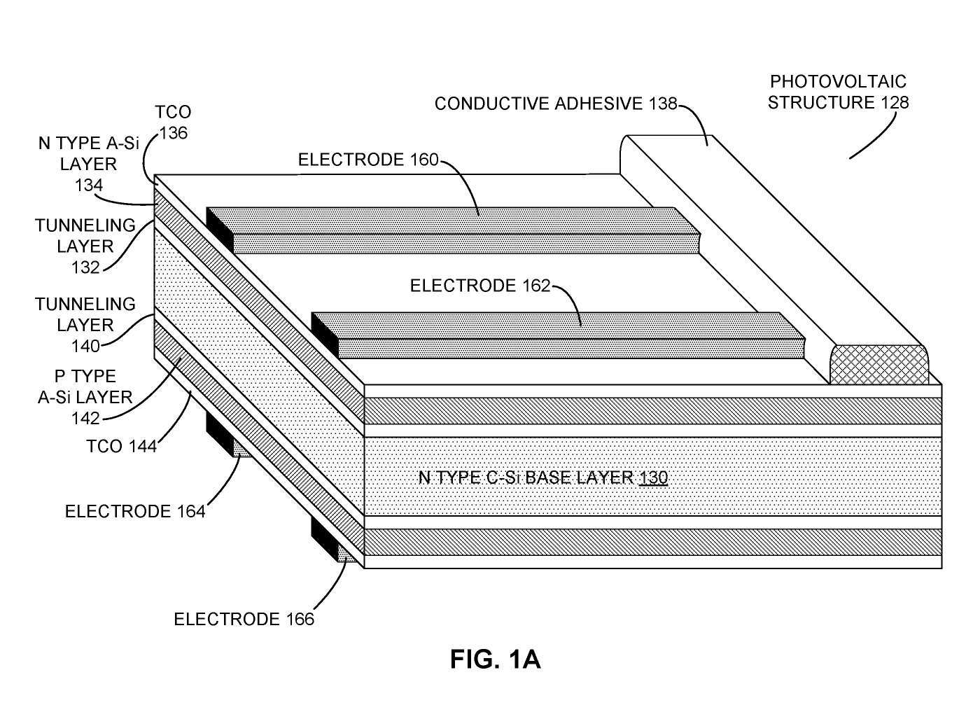

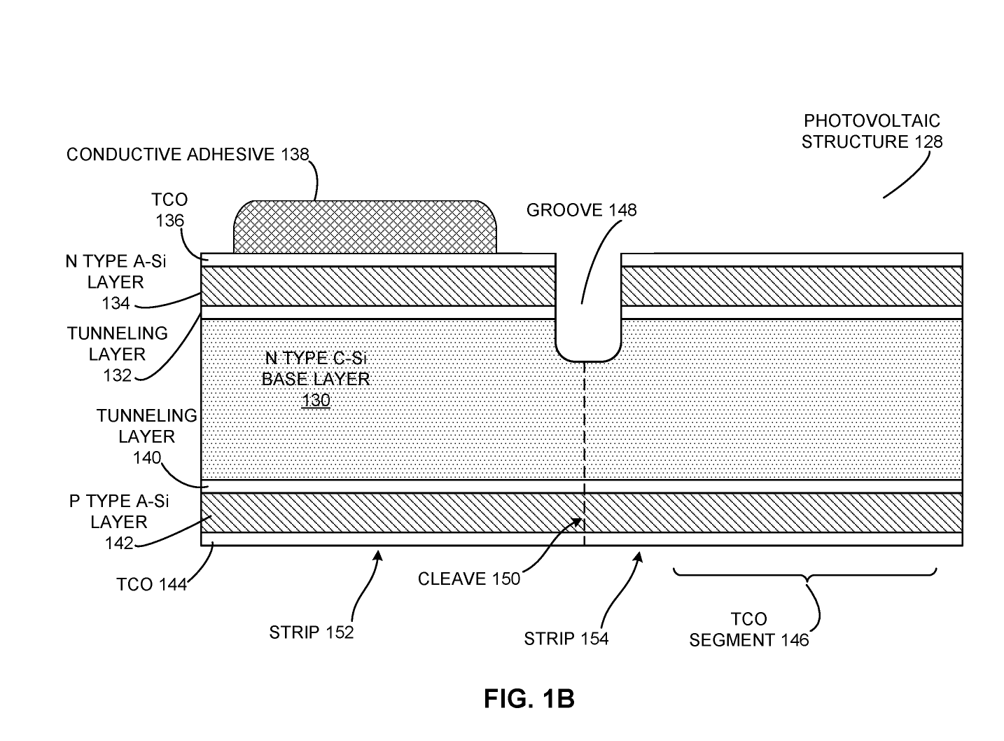

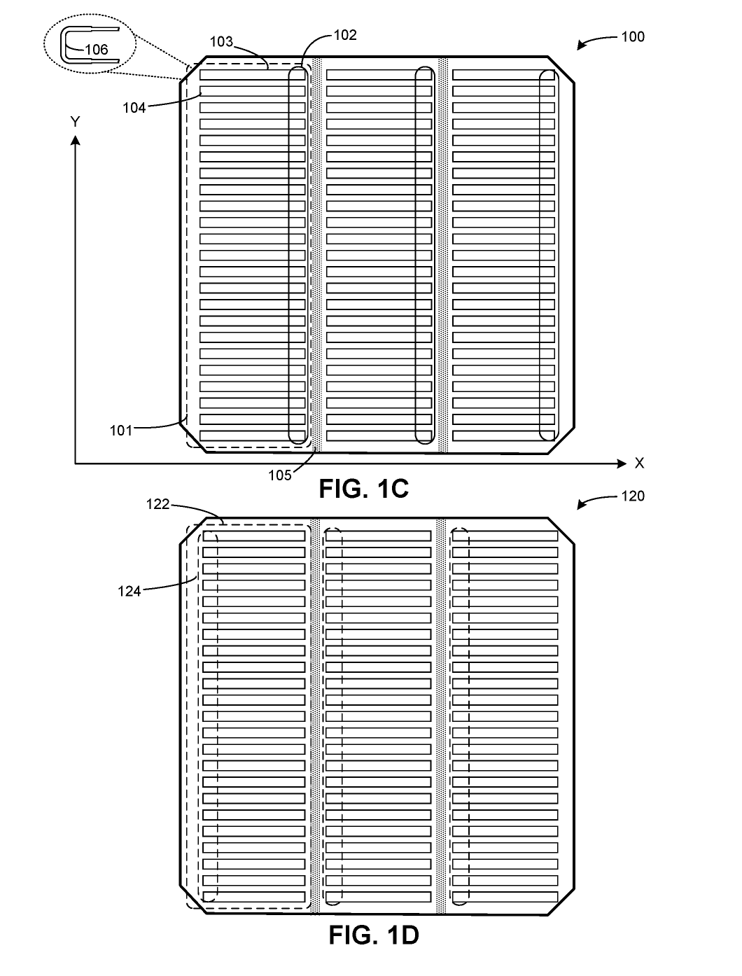

FIG. 1A presents a diagram illustrating an exemplary double-sided tunneling heterojunction solar cell, in accordance with an embodiment of the present invention. In this example, double-sided tunneling heterojunction photovoltaic structure 128 can include N type lightly doped crystalline silicon (c-Si) base layer 130, intrinsic tunneling layer 132, N type heavily doped amorphous silicon (a-Si) surface field layer 134, and transparent conductive oxide (TCO) layer 136. On the backside, photovoltaic structure 128 can include intrinsic tunneling layer 140, P type a-Si emitter layer 142, and TCO layer 144 (including backside TCO segment 146). Finger electrodes 160 and 162 can form a first conductive grid over TCO layer 136, and finger electrodes 164 and 166 can form a second conductive grid over TCO layer 144.

In solar cells, the conductive electrodes, such as finger electrodes 160, 162, 164, and 166, can collect the current generated by photovoltaic structure 128. The finger electrodes can be made of a conductive material, such as copper, and may be laid out in parallel with substantially equal distance from each other.

In some embodiments, conductive adhesive 138 can be laid out on one side of photovoltaic structure 128 (e.g., on a top-facing side) to form a busbar that may collect current from the finger electrodes. Conductive adhesive 138 may be coupled to all the fingers within a segment of photovoltaic structure 128 to aggregate the collected current and facilitate coupling to external leads (such as a metal tab). Note that the lay out pattern of fingers is not limited to lines. Loops and “snake” shaped lay out patterns can be used to reduce the chance of peeling-off of the metal grid.

Conductive adhesive 138 on photovoltaic structure 128 can serve multiple functions. One function of conductive adhesive 138 is to collect the electric current from finger electrodes (e.g., electrodes 160 and 162). A second function is electrical coupling between photovoltaic structure 128 and another neighboring photovoltaic structure. A third function is the physical attachment of photovoltaic structure 128 and the neighboring photovoltaic structure to each other to form a portion of a string. Note that unlike a copper busbar, conductive adhesive 138 is flexible, which may withstand flexing of the photovoltaic structures during the manufacture, transportation, installation, or life-cycle of the solar panels.

Eliminating the copper busbar can also eliminate unnecessary interfaces that may become a point of failure. For example, in a conventional solar panel, a copper interface on a photovoltaic structure may be covered with tin (Sn). So if two neighboring photovoltaic structures were to be connected via a conductive adhesive, this adhesive would need to interface with tin, and would not interface directly to copper. So now, without a copper busbar, the conductive adhesive can interface directly to the transparent conductive oxide (TCO) layer of the photovoltaic structure, without requiring a bond between the conductive adhesive and tin. This can eliminate high copper stresses that can cause a copper busbar to fail, and/or eliminate interfaces that can become a point of failure (e.g., a TCO/Cu interface, a Cu/Sn interface, or a Sn/adhesive interface).

There are several specific considerations in selecting a conductive adhesive for a photovoltaic structure that does not have a metallic busbar. One consideration is the adhesion of conductive adhesive 138 to a TCO layer (e.g., TCO 136 or TCO 144), given that a conductive adhesive that adheres well to copper may not adhere well to a TCO layer. Conductive adhesive 138 may also need to have a good contact resistance to the TCO layer.

Conductive adhesive 138 may also need to adhere well and have a good connectivity to Cu, such as a copper busbar or a copper landing pad of photovoltaic structure 128. In some embodiments, if a copper interface on photovoltaic structure 128 is covered with Sn, conductive adhesive 138 may also need to adhere well and have a good connectivity to Sn.

Other considerations can include the thermal mechanical properties of conductive adhesive 138. For example, conductive adhesive 138 may need to have a specific glass transition temperature (T_{g}). Polimers may change their properties with temperature, depending on which side of the T_{g} their temperature is in. When the temperature is below the material's T_{g}, the material can become hard; when the temperature is above the material's T_{g}, the material can becomes soft and pliable. So a conductive adhesive may need to be selected that can remain soft and flexible during the manufacture of the solar panel, as well as during normal operating conditions. These considerations may require conductive adhesive 138 to have a sufficiently low T_{g} to allow conductive adhesive 138 to remain soft and flexible during the manufacture and lifetime of a solar panel.

The backside tunneling junction, formed by P type a-Si emitter layer 140, intrinsic tunneling layer 140, and N type c-Si base layer 130, can transport away the majority carriers generated by base layer 130. The front side tunneling junction, formed by N type heavily doped a-Si surface field layer 134, intrinsic tunneling layer 132, and base layer 130, can transport away the minority carriers generated by base layer 130, thereby reducing the amount of carrier recombination in base layer 130. Tunneling layers 132 and 140 can passivate the interface between base layer 130 and the two heavily doped a-Si layers while still allowing carriers generated by base layer 130 to enter these a-Si layers due to tunneling effect.

Note that photovoltaic structure 128 can operate with light incident on either side of both sides of the structure. In other words, photovoltaic structure 128 can operate with its surface field layer 134 facing the incident light, or with its emitter layer 142 facing the incident light. Photovoltaic structure 128 can also operate in a bifacial mode, meaning that both surface field layer 134 and emitter layer 142 can receive incident light. Details, including fabrication methods, about double-sided tunneling heterojunction photovoltaic structure 128 can be found in U.S. patent application Ser. No. 12/945,792 (Attorney Docket No. SSP10-1002US), entitled “Solar Cell with Oxide Tunneling Junctions,” by inventors Jiunn Benjamin Heng, Chentao Yu, Zheng Xu, and Jianming Fu, filed 12 Nov. 2010, the disclosure of which is incorporated by reference in its entirety herein.

Exemplary photovoltaic structure 128 shown in FIG. 1A includes an N type lightly doped c-Si base layer. In general, the base layer can be either N or P type doped, or undoped, and can be made of a variety of materials, including c-Si, a-Si, poly-crystalline silicon, or non-silicon materials. Various device structures and designs based on different materials can also be used to construct the photovoltaic structure. For example, the photovoltaic structure can be a wafer-based photovoltaic structure, or a thin film photovoltaic structure, which might have a size and shape different from those of regular wafers.

FIG. 1B shows one example of a photovoltaic structure before being divided into multiple strips, according to one embodiment of the invention. Photovoltaic structure 128 in this example can be divided into strips 152 and 154 by scribing a groove 148, and creating cleave 150 along groove 148. Conductive adhesive 138 can be deposited on top of TCO 136, nearby an edge of strip 152 (e.g., nearby cleave 150).

The tunneling junction between base layer 130 and emitter layer 142 is where the majority carriers are removed. It is therefore preferable that damage to this interface is kept small, such as damage caused by scribing groove 148, handling photovoltaic structure 128, or cleaving photovoltaic structure 128 along groove 148 to produce strips 152 and 154 (e.g., by producing cleave 150). More details of an exemplary photovoltaic structure are provided in U.S. patent application Ser. No. 13/601,441, filed Aug. 31, 2012, entitled “BACK JUNCTION SOLAR CELL WITH TUNNEL OXIDE,” the disclosure of which is hereby incorporated by reference in its entirety herein.

Preferred embodiments of the present invention provide a system that can assemble strips 152 and 154 in a cascaded arrangement without using metallic busbars that can become damaged during fabrication, and without causing damage to the interface between the base layer and emitter layer. Specifically, when strips 152 and 154 are in a cascaded arrangement, conductive adhesive 138 that is deposited on top of TCO 136 of strip 152 can make electrical contact with TCO segment 146 of strip 154. Conductive adhesive 138 can bind TCO 138 and TCO segment 146 together to hold the cascaded arrangement.

Some conventional solar panels can include a single string of serially connected un-cleaved photovoltaic structures. As described in U.S. patent application Ser. No. 14/563,867, it can be more desirable to have multiple (such as 3) strings, each string including cascaded strips, and connect these strings in parallel. Such a multiple-parallel-string panel configuration provides the same output voltage with a reduced internal resistance. In general, a photovoltaic structure can be divided into n strips, and a panel can contain n strings, each string having the same number of strips as the number of regular photovoltaic structures in a conventional single-string panel. Such a configuration can ensure that each string outputs approximately the same voltage as a conventional panel. The n strings can then be connected in parallel to form a panel. As a result, the panel's voltage output can be the same as that of the conventional single-string panel, while the panel's total internal resistance can be 1/n of the resistance of a string (note that the total resistance of a string made of a number of strips can be a fraction of the total resistance of a string made of the same number of undivided photovoltaic structures). Therefore, in general, the greater n is, the lower the total internal resistance of the panel is, and the more power one can extract from the panel. However, a tradeoff is that as n increases, the number of connections required to inter-connect the strings also increases, which increases the amount of contact resistance. Also, the greater n is, the more strips a single photovoltaic structure needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance is, the greater n might need to be to reduce effectively the panel's overall internal resistance. Hence, for a particular type of electrode, different values of n might be needed to attain sufficient benefit in reduced total panel internal resistance to offset the increased production cost and reduced reliability. For example, a conventional silver-paste or aluminum based finger electrode may require n to be greater than 4, because the process of screen printing and firing silver paste onto a photovoltaic structure does not produce ideal resistance between the electrode and the underlying photovoltaic structure. In some embodiments of the present invention, the finger electrodes can be fabricated using a combination of physical vapor deposition (PVD) and electroplating of copper as an electrode material. The resulting copper electrode can exhibit lower resistance than an aluminum or screen-printed-silver-paste finger electrode. Consequently, a smaller n can be used to attain the benefit of reduced panel internal resistance. In some embodiments, n is selected to be three, which is less than the n value generally needed for photovoltaic structures with silver-paste electrodes or other types of electrodes. Correspondingly, two grooves can be scribed on a single photovoltaic structure to allow it to be divided to three strips.

In addition to lower contact resistance, electro-plated copper finger electrodes can also offer better tolerance to micro cracks, which may occur during a cleaving process. Such micro cracks might adversely impact silver-paste-electrode photovoltaic structures. Plated-copper finger electrodes, on the other hand, can preserve the conductivity across the surface of the photovoltaic structure even if there are micro cracks in the photovoltaic structure. The copper finger electrode's higher tolerance for micro cracks can allow one to use thinner silicon wafers to manufacture the photovoltaic structures. As a result, the grooves to be scribed on a photovoltaic structure can be shallower than the grooves scribed on a thicker wafer, which in turn helps increase the throughput of the scribing process. More details on using copper plating to form low-resistance electrode on a photovoltaic structure are provided in U.S. patent application Ser. No. 13/220,532, filed Aug. 29, 2011, entitled “SOLAR CELL WITH ELECTROPLATED GRID,” the disclosure of which is incorporated by reference in its entirety.

FIG. 1C shows an exemplary conductive grid and blank space pattern on a front surface of photovoltaic structure 100, according to one embodiment of the invention. The conductive grid can include three sub-grids, such as sub-grid 101, and can be made of any electrically conductive material, including metallic and non-metallic materials. Photovoltaic structure 100 can include a blank space (e.g., space not covered by electrodes) between neighboring sub-grids, such as blank space 105. The blank space can provide an area where scribing and cleaving can occur. Because the blank space is not covered with any conductive material, the scribing and cleaving can occur without contacting the electrodes. Each sub-grid can function as the front-side grid for the corresponding strip. Hence, this sub-grid-and-blank-space configuration can allow the photovoltaic structure to be divided into three strips.

As shown in FIG. 1C, strip-shaped blank space 105, shown in a shaded rectangle, can separate sub-grid 101 from its adjacent sub-grid. The width of the blank space, such as blank space 105, is chosen to provide sufficient area for the scribing process (e.g., using a laser scribe system) without causing significant damage to the nearby electrodes, and yet sufficiently narrow so that the electrodes can reach the edge of each strip and provide low-resistance collection of the carriers. There may be a tradeoff between a wider blank space that facilitates more error-tolerant scribing operation and a narrower blank space that results in more effective current collection. In one embodiment, the blank space width can be between 0.5 mm and 2 mm. In a further embodiment, the width of such a blank space may be 1 mm.

In order to prevent damaging the emitter junction of the photovoltaic structure, the scribing operation may be performed on the surface corresponding to the surface field layer. For example, if the emitter junction is on the front side of the photovoltaic structure, the scribing may occur to the back surface of the photovoltaic structure. On the other hand, if the emitter junction is on the back side, the scribing may occur on the front surface of the photovoltaic structure.

In some embodiments, sub-grid 101 can be the result of photovoltaic structure 100 having an electroplated copper electrode that exhibits low contact resistance. Each sub-grid can include a number of substantially parallel fingers arranged in the X direction (e.g., finger 104), and can each have a single band of conductive adhesive deposited near the edge, arranged in the Y direction (e.g., conductive adhesive 102). These fingers can collect the carriers generated by the photovoltaic structure and allow them to move toward a band of conductive adhesive 102.

FIG. 1D shows an exemplary conductive grid and blank space pattern on the back surface of photovoltaic structure 100, according to one embodiment of the invention. In this example, the back conductive grid can include three sub-grids, such as sub-grid 122. In one embodiment, the back side sub-grids may correspond to the front side sub-grids. As a result, the back side of the strips can also absorb light to generate electrical energy, thereby allowing the solar panel to operate in a bifacial manner. In the embodiment shown in FIGS. 1C and 1D, the front and back side sub-grids can have similar patterns except that the front and back edge conductive adhesive regions (e.g., adhesive region 124) may be located near opposite edges of the strip. In other words, the conductive adhesive deposited on the front side of the strip may be located near one edge, and may make contact with an adhesive region on the back side that may be located near the opposite edge. In addition, the locations of the blank spaces on the back side may be aligned with the locations of the blank spaces on the front side, such that the conductive grid lines may not interfere with the subsequent cleaving process.

Note that in FIGS. 1C and 1D, the ends of the fingers can be connected by a conductive line to form “loops.” This type of “looped” finger pattern can reduce the likelihood of the fingers from peeling away from the photovoltaic structure after a long period of usage. For example, as shown in FIG. 1C, fingers 103 and 104 can be connected by conductive line 106 to form a loop with rounded corners. Optionally, the sections where the fingers are joined can be wider than the rest of the fingers to provide more durability and prevent peeling. Other finger patterns, such as un-looped straight lines or loops with different shapes, are also possible.

In general, a respective sub-grid can have various types of patterns. For example, a sub-grid can be made of copper, or another metallic material. The dimension of the fingers can be much smaller than that of a busbar, so the fingers typically may not go under as much degradation due to thermal expansion, contraction, and corrosion. Also, the effects of a degredated finger can be significantly smaller than the effects of a degredated metallic busbar. However, to prevent the fingers from corroding over time, the top layer, bottom layer, and sidewalls of the photovoltaic structure can be coated.

Alternatively, a sub-grid can be made of a conductive adhesive, such as a conductive paste or a conductive film with adhesive properties, instead of a metallic material. If the sub-grid is formed using conductive paste or film, sub-grid 101 can be deposited at the same time that conductive adhesive 102 is deposited on photovoltaic structure 100.

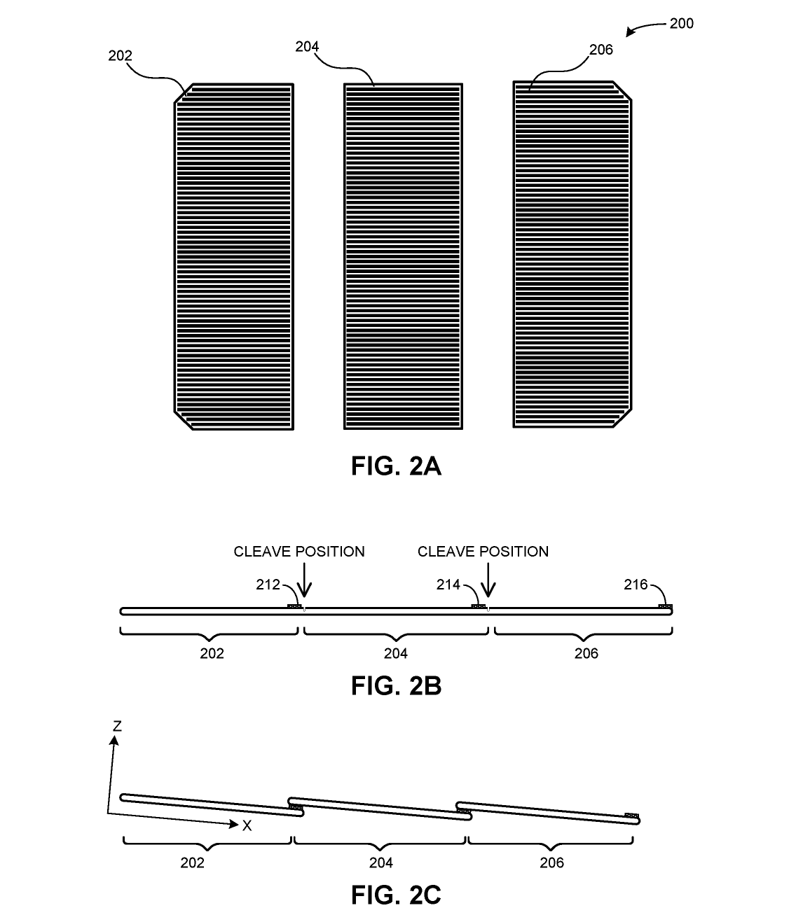

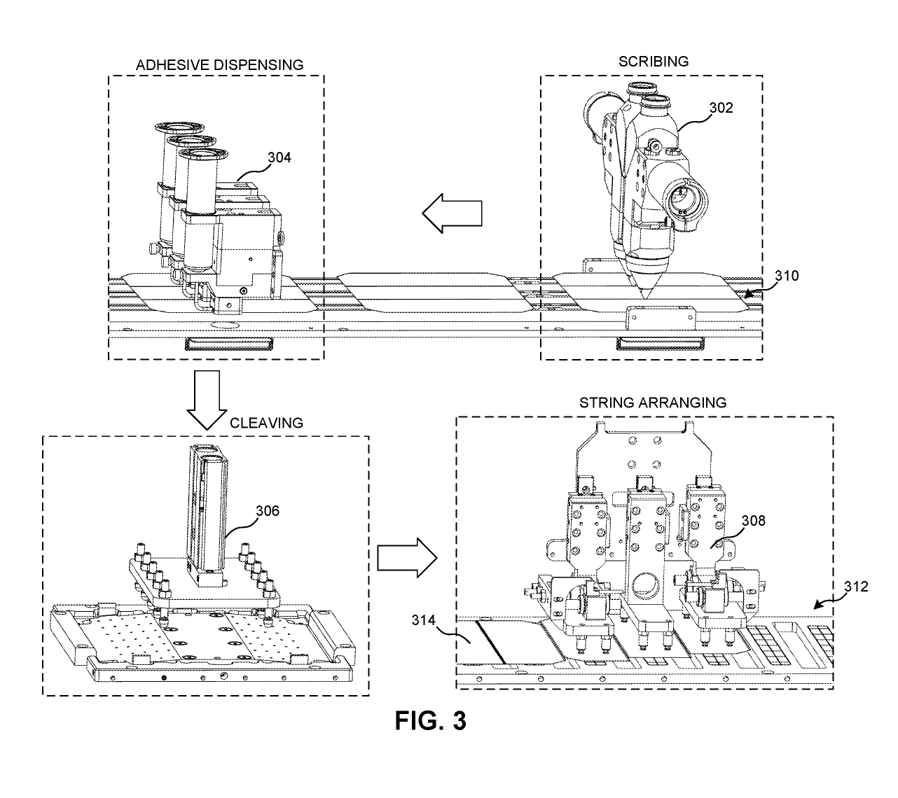

FIG. 2A shows multiple strips 202, 204, and 206, which are the result of separating a photovoltaic structure along a set of grooves, according to one embodiment of the invention. Each strip can include a set of fingers (e.g., copper fingers), and can have a conductive adhesive (e.g., a paste or film) deposited along one edge of the fingers, on one side of the strip (e.g., on the top side).

FIG. 2B shows a cross-sectional view of photovoltaic structure 200 prior to being cleaved, according to one embodiment of the invention. Two scribed grooves can be located between strips 202 and 204, and between strips 204 and 206, respectively. These grooves correspond to the cleave positions. An adhesive-dispensing system can deposit conductive adhesive 212, 214, and 216 near the edge of strips 202, 204, and 206, respectively. After the subsequent cleaving process, the entire photovoltaic structure can be divided, for example, to three strips 202, 204, and 206.

FIG. 2C shows a cascaded arrangement of three strips after a photovoltaic structure is cleaved, according to one embodiment of the invention. In this example, three strips 202, 204, and 206 can be arranged in a cascaded manner, such that the conductive adhesive of one strip (e.g., adhesive 212 on strip 202) is electrically coupled to the fingers on the bottom side of the neighboring strip (e.g., along a bottom edge of strip 204). The conductive adhesive can facilitate both low-resistance contact and physical bonding. Because no conductive tabs or wires are used, such a cascading arrangement can reduce the series resistance due to inter-connection between two strips, and can improve the fill-factor of the panel.

In some embodiments, the strip can include landing pads on a backside of the strip for bussing (not shown). The landing pads can be made of any conductive material, such as copper covered by tin, and can be used to attach a ribbon that couples one string to another. The material used for the landing pads can be selected based on how bussing routes may be coupled to the photovoltaic structure. For example, if the bussing routes are to be soldered onto the landing pads, the conductive (e.g., metallic) landing pads may need to be added to the mask(s) used to fabricate the photovoltaic structure. The material chosen for the landing pad can be selected from any conductive material that can adhere to the solder, such as using copper landing pads.

On the other hand, if the bussing routes are to be glued onto the landing pads using a conductive adhesive, the landing pads can be left bare without copper. The conductive adhesive can be selected from any material that can adhere to the landing pads.

In some embodiments, the bussing routes can be coupled to the photovoltaic structure using a conductive film instead of a conductive adhesive. The conductive film can be coupled onto any conductive material, such as copper (e.g., to a copper finger), or to the photovoltaic structure itself. The conductive film can have the form of a double-sided sticky tape that is conductive. For example, the film itself can be conductive, and the adhesive on both sides of the film can also be conductive. Such a conductive film is simple to apply, as can be spread across the edges of the fingers. Using such conductive film can allow the manufacturing process to avoid using a paste dispenser to apply the adhesive paste to the photovoltaic structure.

Not using a metallic material, such as copper, to create busbars can simplify the manufacturing process of the photovoltaic structures. This in turn can reduce the cost of manufacturing a photovoltaic structure by removing equipment that is costly to install and maintain from the manufacturing process, and by reducing the cost of materials used in the manufacture of the photovoltaic structures.

For example, in a conventional string of photovoltaic structures, a ribbon connector can be used to collect a current from neighboring photovoltaic structures. The busbar in a string can have a current flowing down the string, and helps to be the conductive pass that can transfer the current to a ribbon connector. The ribbon can then function as a high-current contact between neighboring strips, as it's much thicker than a copper busbar.

Not using copper can eliminate the cost of ribbon connectors that would otherwise be needed in the manufacture of the solar panels, in addition to eliminating the cost of the copper. Aside from eliminating the direct costs associated with the copper and the ribbon connectors, not using the copper busbars can also eliminate the manufacturing equipment that would otherwise be necessary to deposit the copper and to install the ribbon connectors onto the photovoltaic structures.

In some embodiments of the present invention, neighboring strips can be arranged in a cascaded arrangement, where the current in the new cascaded string design may not need to travel down a busbar. Rather, the current can travel between the adjacent strips, which can reduce the resistivity of the overall string, and can reduce the need for thick copper busbars between neighboring strips. For example, the current can travel along the fingers within a strip, and can travel through the Z-axis that is orthogonal to the surface of the strip, and onto a “comb” connector that collects current from the string's strips. So rather than traveling the full length of the string (e.g., 2 meters) through the copper, the current may travel the thickness of the cured conductive adhesive (e.g., approximately 20 microns) along the Z-axis.

### String-Forming System

FIG. 3 shows a sequence of steps for processing photovoltaic structures to produce a string, according to one embodiment of the invention. In this example, conveyor 310 can move photovoltaic structures to scribing system 302, which can scribe one or more grooves between two sets of fingers of each photovoltaic structure. Conveyor 310 can then move the photovoltaic structures to adhesive-dispensing system 304, which can dispense a conductive adhesive near one edge of the fingers of the strips, so that after cleaving, these strips can be bonded together in a cascaded arrangement.

After application of the conductive adhesive, the photovoltaic structures can be picked up from conveyor 310 by, for example, a robotic arm (not shown) via a suction device that may be integrated into the robotic arm. The robotic arm can hold the photovoltaic structure by maintaining the suction force while moving the photovoltaic structure toward cleaving system 306. The robotic arm can rotate photovoltaic structures approximately 90 degrees before placing it onto a loading system of cleaving system 306. The loading system may also include a buffer where the photovoltaic structures can be stored before being moved to cleaving system 306.

Cleaving system 306 can receive photovoltaic structures from the loading system, and can divide the photovoltaic structures into strips along the grooves formed by scribing tool 302. After a photovoltaic structure is divided into a number of (e.g., three) strips, string-arrangement system 308 can lift these strips and arrange the strips in a cascaded arrangement while moving the strips to annealing platform 312. String-arrangement system 308 can overlap a leading edge of the three cascaded strips over the trailing edge of string 314, thereby extending string 314.

The sequence of operations shown in FIG. 3 is one of many ways to manufacture cascaded strings. For example, the step of applying the conductive adhesive can occur before scribing or after cleaving. Furthermore, a variety of apparatuses and systems can be used to implement the functions shown in FIG. 3, such as to process multiple photovoltaic structures at a time.

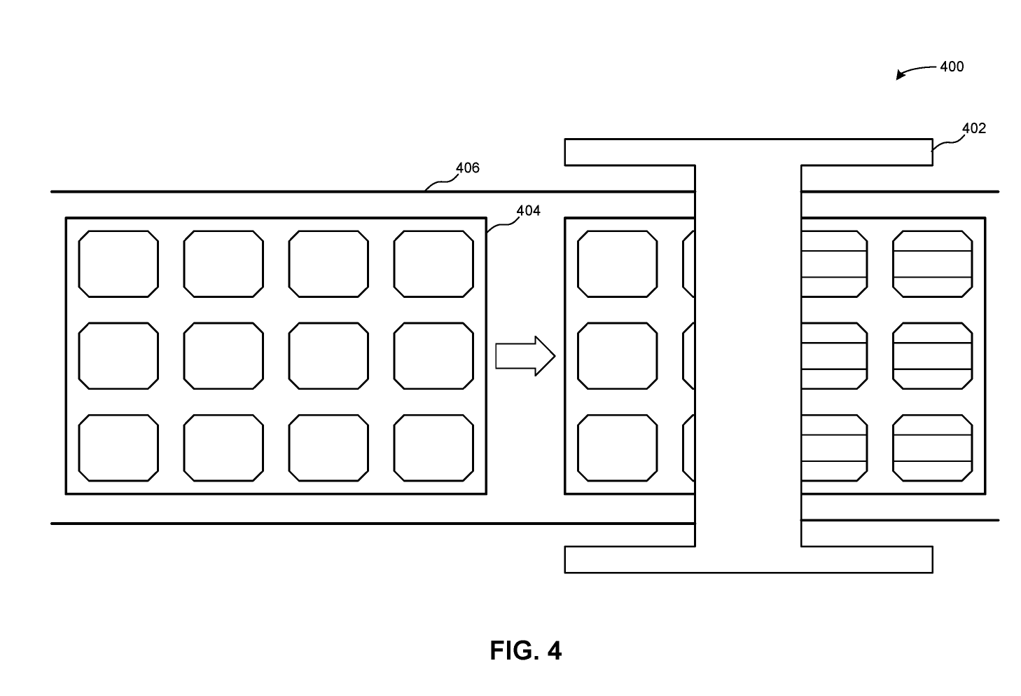

FIG. 4 shows scribing system 400 for simultaneously scribing multiple photovoltaic structures, according to an embodiment of the invention. Scribing system 400 can include overhead platform 402 having a plurality of scribing apparatuses (not shown) that together can be used to scribe multiple photovoltaic structures at a time. A carrier (e.g., carrier 404) can be used to arrange the photovoltaic structures in a predetermined orientation, such as an orientation which mirrors the orientation of the scribing apparatuses on overhead platform 402. For example, the carrier can include a set of slots that hold the photovoltaic structures, and may be arranged in multiple rows (e.g., a two-dimensional lattice arrangement). Once the carrier is aligned or centered to moving platform 406 (e.g., a conveyor), moving platform 406 can move the carrier toward the scribing apparatuses while the carrier keeps the photovoltaic structures in their pre-aligned orientation.

In some embodiments, scribing system 400 can include a vision system, that may include an image sensor and a computer system that can determine the orientation and alignment of the carrier with respect to moving platform 406 and overhead platform 402, and/or can determine the orientation and alignment of the individual photovoltaic structures with respect to the carrier. In some embodiments, if a photovoltaic structure is not oriented correctly (e.g., the photovoltaic structure is rotated 180 degrees from the target orientation) or is not aligned properly into a corresponding slot, a robotic apparatus can adjust the photovoltaic structure to have the desired orientation and alignment. The robotic apparatus can include a robotic arm that may lift a photovoltaic structure using a set of suction nozzles that may create a negative pressure against the surface of the photovoltaic structure. The robotic arm may rotate and shift the photovoltaic structure into the target orientation, for example, while moving platform 606 is shifting the carrier toward overhead platform 402.

Hence, by aligning the photovoltaic structures within a carrier, it may not be necessary to align each photovoltaic structure to a platform or conveyor, or to align each individual scribing apparatus to a photovoltaic structure. Also, because the scribing apparatuses can scribe a groove onto multiple photovoltaic structures at a time, it is possible to run moving platform 406 at a slower and more precise speed. The slower speed of moving platform 406 and the larger and sturdier nature of the carrier (relative to a photovoltaic structure on moving platform 406) can make it less likely that the carrier and its photovoltaic structures would come out of alignment. This increased reliability can produce a higher throughput and yield for the scribing process.

In some variations, during the scribing process, scribing system 400 can skip any photovoltaic structures that are not oriented or aligned properly. In some other variations, each scribing apparatus of scribing system 400 can include an actuator that can align the scribing apparatus to a photovoltaic structure. Then, if a photovoltaic structure is not aligned or oriented properly (e.g., is offset or rotated from its slot by at most a predetermined amount), scribing system can activate the actuator to adjust the alignment of the scribing apparatus during the scribing process to compensate for the photovoltaic structure's incorrect alignment or orientation.

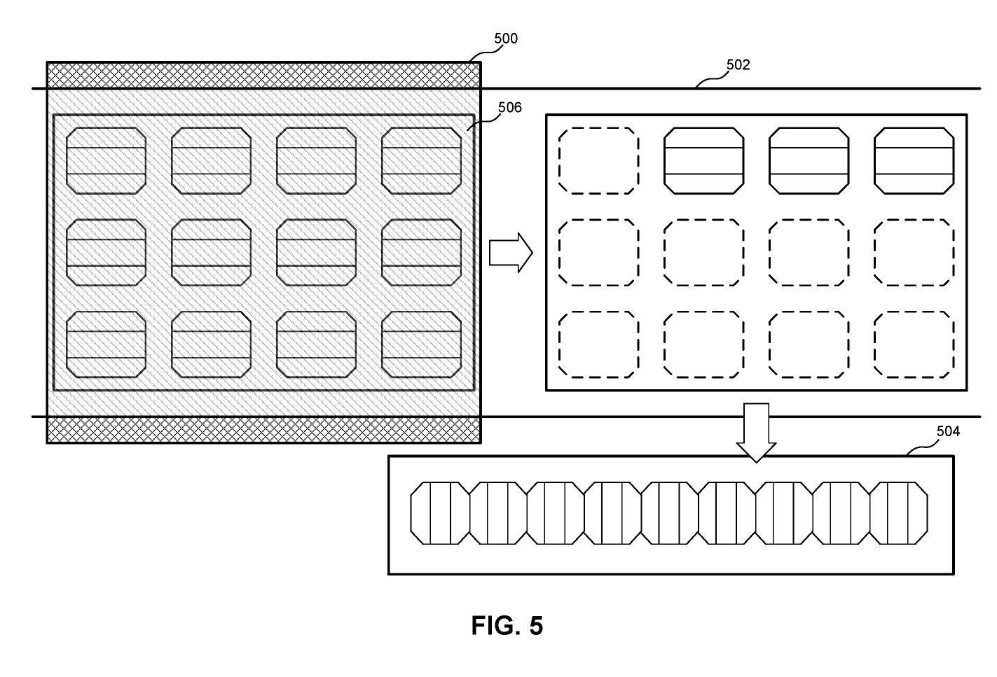

FIG. 5 shows adhesive dispenser 500, according to an embodiment of the invention. Adhesive dispenser 500 can apply a conductive adhesive to multiple strips or photovoltaic structures at a time. For example, as moving platform 502 carries a carrier (e.g., carrier 506) away from the scribing apparatuses, adhesive can be dispensed onto multiple rows of each scribed photovoltaic structure on the carrier. A vision system may include an image sensor and a computer system that can track the movement and alignment of the carrier with respect to adhesive dispenser 500, and may adjust the carrier and/or adhesive dispenser 500 to align them to each other.

In some embodiments, adhesive dispenser 500 can include a screen print system that can align itself to the carrier, which can have the effect of automatically aligning the screen that dispenses the adhesive to the multiple photovoltaic structures. Recall that the photovoltaic structures are divided into multiple strips, and that the strips are later arranged in an overlapping configuration that forms a cascaded string. The pattern of the screen can be configured to apply a conductive adhesive to the edges of the strips that are to receive a cascaded strip.

In some embodiments, adhesive dispenser 500 may also be used to print conductive finger and busbar features on the photovoltaic structure. The conductive adhesive fingers can collect electric current from throughout the photovoltaic structure, and the conductive adhesive busbars can bond neighboring photovoltaic structures to each other as well as collect electric current from the conductive adhesive fingers. This is possible because adhesive dispenser 500 can have a resolution sufficiently high to print finger features using the conductive adhesive. For example, if adhesive dispenser 500 prints the electrode features using a jet paste dispenser, printing the conductive adhesive with the jet can be substantially faster than the process of forming the electrode features on photovoltaic structures using copper. Printing the electrode features using conductive adhesive can therefore speed up the process of producing the photovoltaic structures.

In some embodiments, the curing temperature for conductive adhesive is 150 degrees Celsius, which can be withstood by photovoltaic structures without becoming damaged. Hence, the curing process may not need to be localized to the conductive adhesive, since photovoltaic structures can generally withstand temperatures up to 250 degrees Celsius. In some embodiments, multiple strips can be cured at a time within an oven.

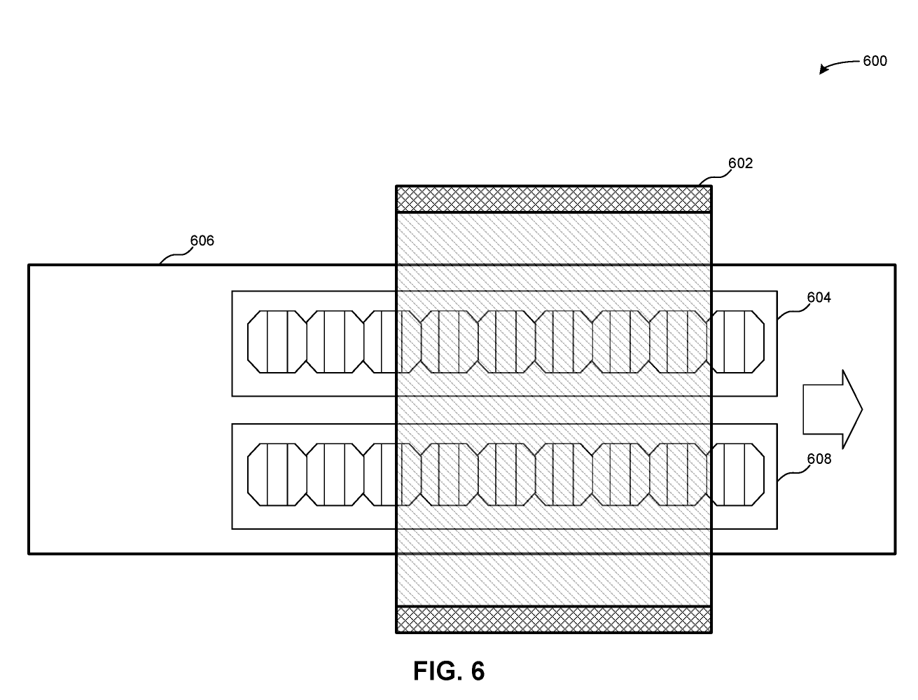

FIG. 6 shows adhesive curing system 600, according to an embodiment of the invention. Adhesive-curing system 600 can include oven 602 (e.g., a hot air curing oven) that can heat air to 150 degrees Celsius, and complete strips (or multiple strips) can be left in oven 602 for 3 minutes to cure the conductive adhesive on the strip.

In some variations, it is possible to cure the adhesive at or near a temperature lower than 150 degrees Celsius by exposing the strip to the heated air for longer than 3 minutes. To make up for the longer curing time, oven 602 can be made sufficiently large to receive and cure multiple strips at a time. For example, oven 602 can have openings at two opposing sides, and the string can be formed on ceramic chuck 604 that passes through oven 602. Ceramic chuck 604 can include a holding apparatus that retains the strips in their cascaded string arrangement. This holding apparatus can include a set of suction nozzles that may hold the strips in their string arrangement by applying a negative pressure against the bottom surface of the strips. Additionally or alternatively, the holding apparatus can include a pocket with a shape and contour that matches the string to hold the strips in the cascaded string arrangement.

As the string is being formed, moving platform 606 (e.g., a conveyor) can pass ceramic chuck 604 through oven 602 at a speed that exposes each strip to heated air for at least the target curing time (e.g., 3 minutes). Larger ovens can allow the platform to move at a faster speed, so the length of oven 602 may be chosen based on the speed at which a string-forming system can add strips to the string. If the curing time is T seconds and the string-forming system can allow ceramic chuck 604 to move at a maximum speed of V meters/second, oven 602 can be made to have a length of V/T meters or smaller.

As another example, oven 602 may be sufficiently large to enclose the complete string. Once the string-forming system has formed the string by arranged a plurality of strips in a cascaded arrangement, the complete string can be inserted into the oven, which can result in a cure time for the string that matches the cure time for the conductive adhesive (e.g., 3 minutes at 150 degrees Celsius). Curing the string at once can allow the throughput to become less sensitive to the curing time, which allows curing the string at a lower temperature. As mentioned earlier, lowering the curing temperature can be beneficial because the lower temperature can provide a more robust process that may be less likely to damage the photovoltaic structures.

In some embodiments, the average cure time per string can be reduced even further by using oven 602 to cure multiple strings at once. For example, the oven-curing process can include placing multiple strings onto the ceramic chuck before placing the ceramic chuck into oven 602, or can involve passing multiple ceramic chucks into oven 602 (e.g., ceramic chucks 604 and 608).

### Control System

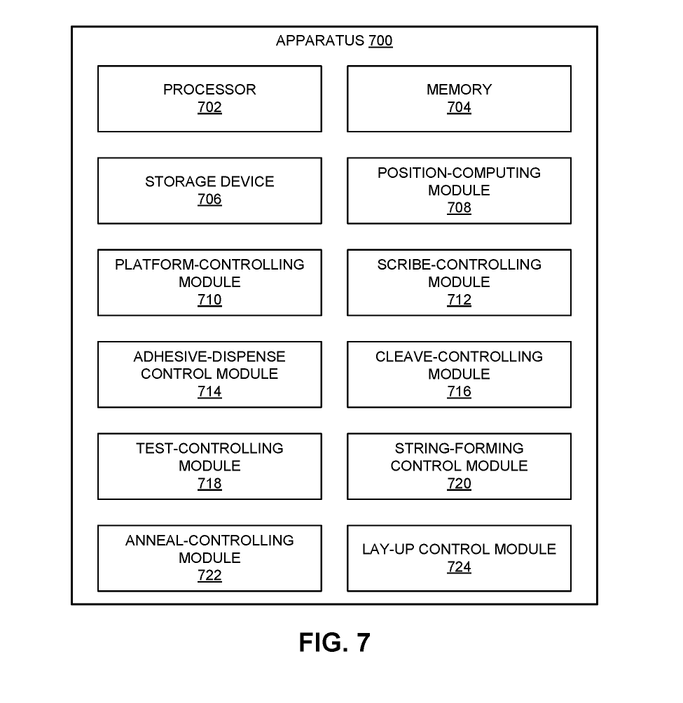

FIG. 7 shows an exemplary system-controlling apparatus, according to an embodiment of the invention. Apparatus 700, which can include the aforementioned computer system, can include a number of modules which may communicate with one another via a wired or wireless communication channel. Apparatus 700 may be realized using one or more integrated circuits, and may include fewer or more modules than those shown in FIG. 7.

System-controlling apparatus 700 can include processor 702, memory 704, and storage device 706. Memory 704 can include volatile memory (e.g., RAM) that serves as a managed memory, and can be used to store one or more memory pools. In some embodiments, storage device 706 can store an operating system, and instructions for monitoring and controlling the scribing process.

In this example, apparatus 700 can include position-controlling module 708, platform-controlling module 710, scribe-controlling module 712, adhesive-dispense module 714, testing module 716, string-forming module 718, and anneal-controlling module 720.

Platform-controlling module 710 can cause a platform (e.g., a moving platform, or a conveyor) to move a carrier that holds a set of photovoltaic structures from a loading station to the scribing station, to an adhesive-dispense station, and subsequently toward a cleaving and testing station. Position-computing module 708 may analyze images from a vision system to determine the location of the carrier on the platform, and to determine the alignment of the photovoltaic structures and its fingers. Position-computing module 708 can periodically (e.g., at predetermined time intervals) calculate the position of the carrier relative to the platform and relative to each station, while the platform moves the carrier from station to station. For example, position-computing module 712 can calculate the carrier's position based on an image captured by the vision system, a corresponding time stamp, and the speed to the platform.

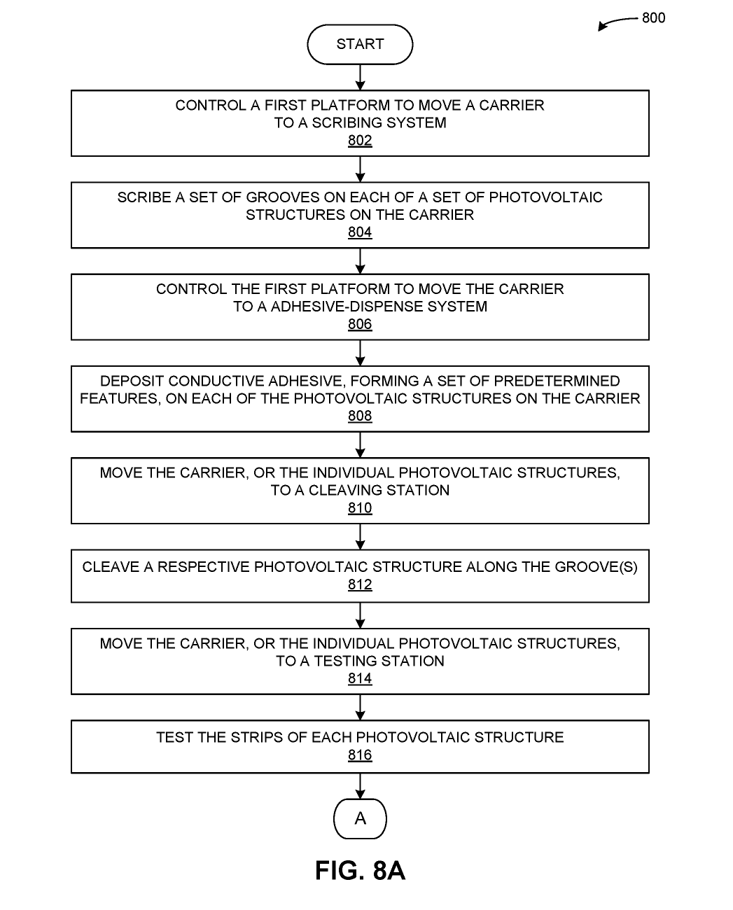

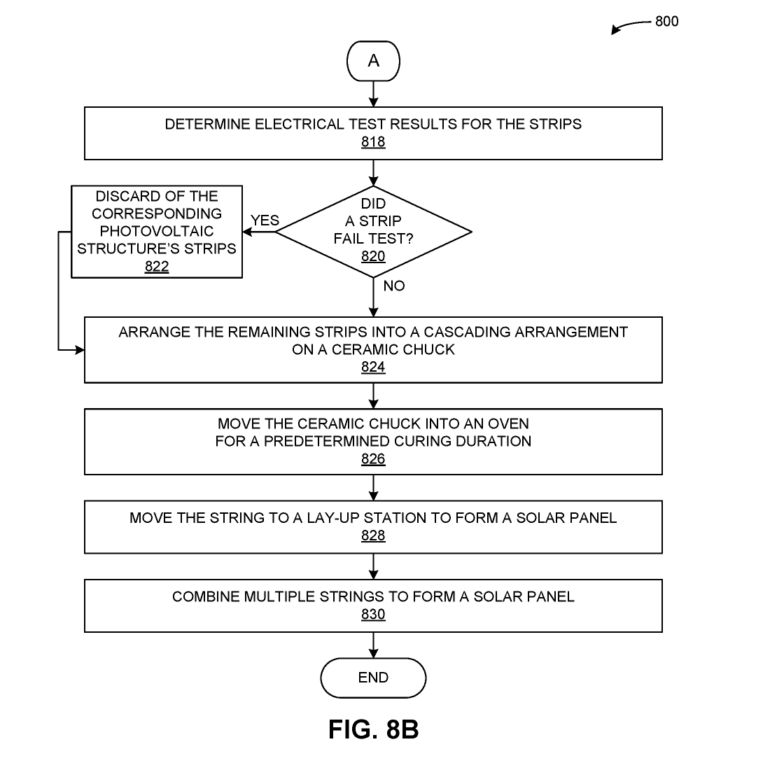

FIGS. 8A and 8B show exemplary method 800 for processing a plurality of photovoltaic structures in parallel to form a string, according to an embodiment of the invention. During operation, platform-controlling module 710 can control a first platform to move a carrier to a scribing station (operation 802). Scribe-controlling module 712 can then scribe a set of grooves on each of a set of photovoltaic structures on the carrier (operation 804). For example, scribe-controlling module 712 can activate an actuator to align a scribing tool to a predetermined distance from a photovoltaic structure's set of fingers, such as, prior to the photovoltaic structure reaching the scribing tool, or while the conveyor is moving the photovoltaic structure underneath the scribing tool. Scribe-controlling module 716 can activate the scribing tool at a predetermined position (e.g., when the position of a leading edge of the photovoltaic structure reaches the scribing tool), and subsequently deactivate the scribing tool at another position (e.g., when the position of a trailing edge of the photovoltaic structure reaches the scribing tool).

Platform-controlling module 710 can then control the first platform to move the carrier to an adhesive-dispensing system (operation 806), and adhesive-dispense control module 714 can control a the adhesive-dispensing system to deposit a conductive adhesive (e.g., a paste or film) on a top surface of each photovoltaic structure on the carrier, in a predetermined pattern (operation 808). In some embodiments, the predetermined pattern can include a band of conductive adhesive across each set of fingers on each photovoltaic structure in the carrier. In some variations, the predetermined pattern can include a set of finger and busbar pattern formed using the conductive adhesive.

Next, platform-controlling module 710 can move the carrier, or the individual photovoltaic structures, to a cleaving station (operation 810). Cleave-controlling module 716 can then control a cleaving system that can cleave the photovoltaic structures on the carrier along their scribed grooves (operation 812). In some embodiments, the cleaving system may cleave a photovoltaic structure along a set of grooves while the photovoltaic structure is in the carrier. For example, each slot in the carrier can include a pair of fulcrums along an inner edge of two grooves of the photovoltaic structure. The cleaving system may cleave multiple photovoltaic structures on the carrier by lowering a set of cleave tips that gently press down on two outer strips of the photovoltaic structure.

In some other embodiments, the cleaving system may transfer each photovoltaic structure from the carrier to a cleaving station, and rests the photovoltaic structure on a platform at the cleaving station having a pair of fulcrums. The cleaving system may then lower a set of cleave tips to press down on the outer strips of the photovoltaic structure, to cleave the photovoltaic structure along the set of grooves while the photovoltaic structure rests on the cleaving station.

Platform-controlling module 710 can move the carrier, or the individual photovoltaic structures, to a testing station once they are cleaved (operation 814). Test-controlling module 718 can test electrical properties of the photovoltaic structures, either at the same time or one at a time (operation 816), and determines the test results for the individual strips (operation 818).

If test-controlling module 718 determines that a strip failed the electrical test (operation 820), string-forming module 720 can configure a string-forming system to discard photovoltaic structures whose strips have failed the test (operation 822). String-forming module 720 can also configure the string-forming system to arrange the remaining strips to form a string (operation 824). In some embodiments, string-forming module 720 can form the string on a ceramic chuck that can withstand high temperatures.

Anneal-controlling module 722 can move the ceramic chuck into or through the oven so that the individual strips are exposed to heated air for a predetermined curing duration. In some embodiments (operation 826), the heated air has a temperature of 150 degrees Celsius, and the strips are exposed to the heated air for three minutes.

Once the conductive adhesive on the string is cured, Platform-controlling module 710 can move the string to a lay-up station (operation 828), and lay-up control module 722 can operate the lay-up station to combine multiple strings to form a solar panel (operation 830).

### Testing Apparatus

In some embodiments, a testing apparatus can test electrical current and voltage properties of a strip to produce a current-voltage characteristic curve (IV curve) by measuring the overall current that can be conducted by the fingers across the strip. If conductive adhesive has been used to form the busbars (and in some embodiments, the fingers as well), the testing apparatus may be configured to interoperate with the landing pads of the strip. This can test the strip's electrical properties when the conductive adhesive has not yet been cured by measuring the current that is transferred to the landing pad by the conductive adhesive.

Alternatively, if the strip has copper fingers, the testing apparatus may test the efficiency of a strip by coupling a probe to multiple fingers on the strip to gather and test the net current collected from the multiple fingers, or to simultaneously test the current from each individual finger. For example, the probe can have the form of a mesh that is placed on top of the photovoltaic structure, such that the mesh may include a set of contact surfaces (e.g., an elongated contact) that each can become aligned with, and can come in contact with, a corresponding finger. Testing the strip's electrical properties from the fingers directly can be beneficial when the conductive adhesive has not been applied to collect current from the fingers, since the conductive adhesive is used to conduct current to a landing pad on a strip without a copper busbar.

### Lay-Up Tool

Multiple strings can be assembled to form a solar panel by placing the strings side-by-side in a frame, and electrically coupling each string to its neighboring string(s). For example, a “comb” can be attached to each string to collect an electric current from the string. The comb can include a set of contacts that can be electrically coupled to the various landing pads throughout the length of the string, and can collect the electric current from the landing pads. The comb can have a pair of cables, and each of the two cables can be attached to a neighboring string's comb via conductive adhesive (e.g., a conductive paste or film), solder, etc. The remaining cables from opposing sides of the solar panel can be used to collect the solar panel's overall output current.

In some embodiments, each contact on the comb can be soldered onto a landing pad on the string. However, the soldering process can be difficult to perform, as it oftentimes requires heating the solder using hot air or a metal tip, and given that solder can easily move away from the target location when melted. Moreover, the solder can become rigid when cooled, which can cause the contact to separate from the landing pad if twisted or moved while the solar panel is being assembled or installed.

In some embodiments, to reduce the risk of having contacts break away from landing pads, the contact can be adhered to the landing pad by applying conductive adhesive to the string instead of solder. The conductive adhesive can then be cured locally (e.g., by applying heat to the contact and/or to the landing pad), or in an oven that cures the conductive adhesive throughout the solar panel at once. The malleable nature of the conductive adhesive under normal operating temperatures can tolerate certain movements by the contacts or the comb without losing hold of the contact or the landing pad.

In another embodiment, the difficult soldering process can be avoided by using a conductive film to adhere a contact to a landing pad instead of solder. The film itself can be conductive, and can have adhesive adhesive on both sides of the film that can also be conductive. To attach a comb to a string, conductive film can be applied to the locations of the string that are to become electrically coupled to the comb's connectors (e.g., to an exposed segment of a landing pad), and a comb connector can be attached to the exposed surface of the conductive film.

The data structures and code described in this detailed description can typically be stored on a computer-readable storage medium, which may be any device or medium that can store code and/or data for use by a computer system. The computer-readable storage medium can include, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system can perform the methods and processes embodied as data structures and code and stored within the computer-readable storage medium.

Furthermore, the methods and processes described above can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules can perform the methods and processes included within the hardware modules.

The foregoing descriptions of embodiments of the invention have been presented for purposes of illustration and description only. They are not intended to be exhaustive or to limit the invention to the forms disclosed. Accordingly, many modifications and variations may be apparent to practitioners skilled in the art. Additionally, the above disclosure is not intended to limit the invention. The scope of the invention is defined by the appended claims.

What is claimed is:

1. A busbarless photovoltaic structure, comprising:
a first set of finger electrodes positioned along a first side of the photovoltaic structure, wherein a respective finger electrode on the first side is configured to harvest current from the first side of the photovoltaic structure;
a segment of conductive adhesive on the first side covering one edge of the finger electrodes, wherein the conductive adhesive is configured to transfer a current harvested by the finger electrodes to a conductor.

2. The photovoltaic structure of claim 1, wherein a respective finger electrode includes an electroplated copper layer.

3. The photovoltaic structure of claim 1, wherein the segment of conductive adhesive has an elongated shape and is perpendicular to the finger electrodes.

4. The photovoltaic structure of claim 1, wherein the finger electrodes are substantially parallel to each other.

5. The photovoltaic structure of claim 1, wherein the photovoltaic structure is a double-sided tunneling heterojunction photovoltaic structure, which includes:
a base layer;
first and second intrinsic tunneling layers deposited on both surfaces of the base layer;
an amorphous silicon emitter layer; and
an amorphous silicon surface field layer;
wherein the photovoltaic structure can absorb light from the first side and a second side of the photovoltaic structure.

6. The photovoltaic structure of claim 5, further comprising:
a plurality of finger electrodes positioned along the second side of the photovoltaic structure, wherein a respective finger electrode on the second side is configured to harvest a current from the second side of the photovoltaic structure.

7. The photovoltaic structure of claim 1, wherein the photovoltaic structure is obtained by dividing a substantially square shaped photovoltaic structure.

8. A solar panel, comprising:
a plurality of photovoltaic strips arranged into a plurality of subsets, each subset comprising a number of photovoltaic strips electrically coupled in series, wherein a respective photovoltaic strip of the subset comprises:
a plurality of finger electrodes on a first side of the respective photovoltaic strip; and
a segment of conductive adhesive on the first side covering one edge of the finger electrodes, wherein the conductive adhesive is configured to collect a current harvested by the finger electrodes;
wherein the subsets of photovoltaic strips are electrically coupled in parallel.

9. The solar panel of claim 8, wherein a respective photovoltaic strip in a subset is obtained by dividing a substantially square shaped photovoltaic structure.

10. The solar panel of claim 8, wherein the photovoltaic structure is a double-sided tunneling heterojunction photovoltaic structure that can absorb light from the first side and a second side of the photovoltaic structure.

11. The solar panel of claim 10, further comprising:
a plurality of finger electrodes positioned along the second side of the photovoltaic strip, wherein a respective finger electrode on the second side is configured to harvest a current from the second side of the photovoltaic strip.

12. The solar panel of claim 1, wherein a respective finger electrode includes an electroplated copper layer.

13. The solar panel of claim 11, wherein the conductive adhesive on the first side of the respective photovoltaic strip is in contact with an edge of the second side of a neighboring photovoltaic strip in the subset.

14. The solar panel of claim 13, wherein the conductive adhesive is electrically coupled to finger electrodes on the second side of the neighboring photovoltaic strip.

15. A method for fabricating a solar panel, comprising:
electrically coupling a plurality of photovoltaic strips in series to form a string, wherein a respective photovoltaic strip comprises:
a plurality of finger electrodes on both sides of the respective photovoltaic strip; and
a segment of conductive adhesive on a first side of the photovoltaic strip, wherein the conductive adhesive covers one edge of finger electrodes on the first side;
electrically coupling multiple strings in parallel; and
applying a front-side cover and a back-side cover over the strings.

16. The method of claim 15, further comprising:
obtaining a plurality of substantially square shaped photovoltaic structures;
dividing each substantially square shaped photovoltaic structure into multiple photovoltaic strips.

17. The method of claim 15, wherein electrically coupling the plurality of photovoltaic strips in series involves:
overlapping a bottom edge of a first photovoltaic strip on top of conductive adhesive on a top edge of a second photovoltaic strip, wherein the conductive adhesive electrically couples finger electrodes on the bottom side of the first photovoltaic strip to finger electrodes on the top side of the second photovoltaic strip.

18. The method of claim 15, further comprising:
curing conductive adhesive on the string to physically couple the strips in the string.

19. The method of claim 18, wherein curing conductive adhesive involves:
exposing the conductive adhesive to air heated to 150 degrees Celsius for 3 minutes.

20. The method of claim 15, wherein conductive adhesive on the respective photovoltaic strip transfers current harvested from the finger electrodes to a conductive contact, and wherein electrically coupling multiple strings in parallel involves:
coupling a pair of contacts of a first string to a pair of contacts of a second string.

21. A system for depositing conductive adhesive along an edge of a set of finger lines, the system comprising:
a carrier-detecting module configured to detect an orientation of a carrier on a platform;
an alignment module configured to verify that the carrier is substantially aligned to an adhesive dispenser; and
an adhesive dispenser configured to deposit conductive adhesive on a set of photovoltaic structures residing on the carrier, wherein a respective photovoltaic structure comprises a plurality of parallel elongated conductive regions on a surface of the photovoltaic structure, and wherein the adhesive dispenser deposits a band of conductive adhesive on the surface and overlapping the plurality of conductive regions, orthogonal to the conductive regions and near an edge of the conductive regions.

22. The system of claim 21, wherein the adhesive dispenser deposits the conductive adhesive on the set of photovoltaic structures at the same time.

23. The system of claim 21, wherein the adhesive dispenser comprises at least one of:
a screen printer; and
a plurality of adhesive-dispensing jets.

24. The system of claim 21, wherein in response to the carrier not being substantially aligned to the adhesive dispenser, the alignment module is further configured to align the adhesive dispenser to the carrier.

25. The system of claim 21, wherein in response to the carrier not being substantially aligned to the adhesive dispenser, the alignment module is further configured to align the carrier to the adhesive dispenser.

26. A system for curing conductive adhesive on multiple photovoltaic structure strips arranged into a string, the system comprising:
a ceramic chuck comprising a holding apparatus adapted to hold multiple strips, wherein a respective strip comprises:
a plurality of parallel elongated conductive regions on a surface of the strip; and
a band of conductive adhesive on the surface, wherein the band of conductive adhesive is orthogonal to the conductive regions and along an edge of the conductive regions;
an oven comprising a heated chamber for curing conductive adhesive on multiple strips; and
a chuck-moving apparatus configured to insert the ceramic chuck into the heated chamber of the oven to cure the conductive adhesive on the multiple strips.

27. The system of claim 26, wherein the holding apparatus comprises a platform with a cavity for each of the multiple strips.

28. The system of claim 26, wherein the holding apparatus comprises a platform with at least one device adapted to hold a respective strip by creating a pressure difference.

29. The system of claim 26, wherein the chuck-moving apparatus inserts the complete ceramic chuck into the heated chamber of the oven for a predetermined curing duration.

30. The system of claim 26, wherein the oven cures the conductive adhesive on a respective strip at 150 degrees Celsius, for 3 minutes.
